(19) United States
(12) Patent Application Publication
(10) Pub. No.: US 2005/0146060 A1
(43) Pub. Date: Jul. 7, 2005

(54) Peltier module and manufacturing method therefor

(76) Inventor: Yukitoshi Suzuki, Hamamatsu-shi (JP)

Correspondence Address: DICKSTEIN SHAPIRO MORIN & OSHINSKY LLP, 1177 AVENUE OF THE AMERICAS (6TH AVENUE), 41 ST FL., NEW YORK, NY, 10036-2714, US

(21) Appl. No.: 10/973,471

(22) Filed: Oct. 27, 2004

(30) Foreign Application Priority Data
Oct. 29, 2003 (JP) 2003-369096

(51) Int. Cl. H01L 35/28

(52) U.S. Cl. 257/930

(57) ABSTRACT

A Peltier module comprising a plurality of thermoelectric semiconductor elements between substrates in connection with electrodes. It is manufactured by four steps, namely, an application step in which a resist onto the substrate, a hollow formation step in which the resist is deformed into a resist pattern having a lattice-like shape and a plurality of hollows, an electrode formation step in which the electrodes are formed in the hollows of the resist pattern, and a removal step in which the resist pattern is removed from the substrate, wherein the resist is made of an acrylic resist including acrylic polymer, multifunctional acrylate, and photosensitive agent. The electrodes are formed and arranged by use of the resist pattern having the hollows in such a way that an aspect ratio D/S, which is defined using an electrode thickness D and an inter-electrode space S, is set to 1.25 or more.

### BACKGROUND OF THE INVENTION

1. Field of the Invention

This invention relates to Peltier modules and manufacturing methods for manufacturing Peltier modules by use of photolithography techniques.

This application claims priority on Japanese Patent Application No. 2003-369096, the content of which is incorporated herein by reference.

2. Description of the Related Art

Peltier modules are thermoelectric conversion devices, which operate as heat pumps upon application of dc currents so as to perform cooling, heating, and temperature control.

FIGS. 22A to 22C show a typical example of a Peltier module, which comprises a ceramic substrate 2, a plurality of thermoelectric semiconductor elements 3, and a ceramic substrate 4. Herein, the thermoelectric semiconductor elements 3 are arranged on the ceramic substrate 2, and the ceramic substrate 4 is arranged on the upper ends of the thermoelectric semiconductor elements 3, which are thus sandwiched between the ceramic substrates 2 and 3.

The thermoelectric semiconductor elements 3 comprise a plurality of P-type thermoelectric semiconductor elements 5 and a plurality of N-type thermoelectric semiconductor elements 6. The P-type thermoelectric semiconductor elements 5 and the N-type thermoelectric semiconductor elements 6 are electrically connected in series such that both ends thereof join a plurality of copper electrodes 7 and 8, which are attached to the ceramic substrates 2 and 4 respectively. That is, each of the copper electrodes 7 and 8 is connected with a pair of the P-type thermoelectric semiconductor element 5 and the N-type thermoelectric semiconductor element 6. In addition, leads 9a connected with a power source E (not shown) are connected with copper electrodes 7a, which terminate the copper electrodes 7 electrically connected in series, so as to allow dc currents to flow therethrough.

Next, a method for producing the copper electrodes 7 attached to the substrate 2 in the aforementioned Peltier module 1 will be described with reference to FIGS. 23A to 23F, wherein the other copper electrodes 8 attached to the substrate 4 can be produced similarly, hence, the description thereof will be omitted.

As shown in FIG. 23A, a metal layer 2a serving as a bed is formed on the upper surface of the substrate 2. As shown in FIG. 23B, a resist 10 such as a dry film is applied to the metal layer 2a. As shown in FIG. 23C, the photolithography technique for realizing transfer of desired shapes is used to cause photochemical reactions on the resist 10, which are thus transformed in a resist pattern 10a having a lattice-like pattern. Herein, hollows 10b are formed by the resist pattern 10a, which acts as a mask. As shown in FIG. 23D, plating is performed to form copper electrodes 7 in the hollows 10b. Then, the resist pattern 10a is separated from the substrate 2 as shown in FIG. 23E. Lastly, prescribed portions of the metal layer 2a beneath that resist pattern 10a are removed by etching and the like; thus, it is possible to produce an assembly shown in FIG. 23F in which the copper electrodes 7 are arranged with prescribed distances therebetween on the substrate 2 via the residuals of the metal layer 2a.

Next, conventionally known photolithography techniques for removing resists will be described.

Conventionally, photolithography techniques are used to form fine and precise circuit patterns, which are necessary in producing printed wiring boards (PWB), large-scale semiconductor integration (LSI) circuits, and liquid crystal displays (LCD) as well as fine workpieces such as photomasks and lead frames.

In the conventionally known photolithography technique, a resist (i.e., a photosensitive resin compound in which a photosensitive polymer material (or a photosensitive high-molecular substance) is dissolved in an organic solvent is applied to a substrate having a treated layer on its surface, wherein pre-baking is performed to evaporate excess organic solvent, thus forming a resist film. Light is irradiated onto prescribed areas of the resist film, which is thus altered in solubility in a developer. Exposure is normally performed using a photomask, via which light is irradiated onto the resist film in a prescribed pattern. Then, the developer is used to dissolve and remove unnecessary areas of the resist film, so that a prescribed resist pattern is formed on the substrate. Thus, the treated layer on the substrate is subjected to treatment by using the resist pattern as a mask. For example, it is possible to use a variety of treatments such as etching, ion implantation, and doping. Lastly, the “unwanted” resist pattern is removed from the substrate. This is disclosed in various papers such as Japanese Patent Application Publication No. 2000-66417 (see page 2).

Next, the operating principle of the Peltier module 1 will be described with reference to FIG. 24.

The power source (i.e., a voltage source) E is connected with the copper electrodes 7 so as to cause a dc current flow towards the N-type thermoelectric semiconductor element 6, whereby electrons move from the copper electrode 8 to the copper electrodes 7, so that heat is correspondingly transferred from the copper electrode 8 to the copper electrodes 7. In the P-type thermoelectric semiconductor element 5, holes move from the copper electrode 8 to the copper electrode 7 so as to act like electrons in the N-type thermoelectric semiconductor element 6, so that heat is transferred from the copper electrode 8 to the copper electrode 7. At this time, when heat dissipation is sufficiently performed in the side of the copper electrode 7, it is possible to actualize continuous endothermic operation in the side of the copper electrode 8.

In the conventionally known method that is adapted to the Peltier module 1 to cause separation of the resist pattern 10a from the substrate 2, the resist pattern 10a is subjected to swelling so as to cause positional deviations in the joining surface of the metal layer 2a joining therewith. Herein, it is required that an aspect ratio D/S (which is calculated by use of an electrode thickness ‘D’ and an inter-electrode space S) be set to 1.25 or less. In addition, a prescribed relationship of H≧D (where ‘H’ denotes a resist height) should be established so that plating does not overflow from the hollow of the resist pattern.

When the resist pattern 10a is separated from the metal layer 2a under the condition where D/S>1.25, the resist pattern 10a is subjected to swelling but is difficult to be extracted from the space between the copper electrodes 7, which are positioned adjacent to both ends of the resist pattern 10a so as to inwardly press the resist pattern 10a therebetween. When the resist pattern 10a is compulsorily separated from the metal layer 2a, some portions of the resist pattern 10a must remain on the metal layer 2a. For this reason, it is very difficult to actualize the aforementioned relationship of D/S>1.25. Actually, testing results (which will be described later in conjunction with embodiments) show that after separation, residuals occur in conventionally known resist patterns under the condition where D/S>1.25.

In order to establish the relationship of D/S≦1.25, it is necessary to increase the inter-electrode space S (i.e., the width of the resist pattern 10a) relative to the electrode thickness D (i.e., the height of the resist pattern 10a), wherein the overall area of the copper electrodes 7 installed in the Peltier module should be limited relative to the overall area of the substrate 2. This limits the overall area for installing the thermoelectric semiconductor elements in the Peltier module 1. Herein, it is impossible to increase the number of electrons and holes, which are used for heat transfer (or thermal conduction) in the Peltier module. In other words, it is very difficult to produce a high-performance Peltier module 1 that is capable of transferring a relatively large amount of heat.

Even though the width S of the resist pattern 10a is reduced, the thickness of the copper electrode 7 formed in the hollow 10b is reduced due to the relationship of D/S≦1.25, so that the sectional area of the copper electrode 7 decreases so as to increase an electric resistance thereof and Joule heat, which in turn increase power loss, whereby the Peltier element 1 should be deteriorated in performance.

### SUMMARY OF THE INVENTION

It is an object of the invention to provide a Peltier module having high performance and a manufacturing method therefor, wherein an aspect ratio D/S can be set to 1.25 or more.

A Peltier module of this invention basically comprises a plurality of thermoelectric semiconductor elements, which are sandwiched between a pair of electrodes made of ceramics, wherein both ends of the thermoelectric semiconductor elements are respectively attached to the substrates via copper electrodes. Herein, an aspect ratio D/S, which is defined using an electrode thickness D and an inter-electrode distance S, is set to 1.25 or more.

A manufacturing method of the Peltier module basically comprises four steps, namely, an application step in which a resist is applied onto the surface of a substrate, a hollow formation step in which the resist is transformed into a resist pattern having a lattice-like shape having a plurality of hollows by use of a photolithography technique, an electrode formation step in which a plurality of electrodes are formed in the hollows of the resist pattern, and a removal step in which the resist pattern is removed from the substrate, wherein as the resist, it is possible to use an acrylic resist including acrylic polymer, multifunctional acrylate, and photosensitive agent.

Since the resist pattern is formed using the aforementioned acrylic resist including acrylic polymer, multifunctional acrylate, and photosensitive agent, it is possible to use organic amine in dissolving the resist pattern, which is separated from the substrate after the electrode formation step. That is, even when the aspect ratio D/S is set to 1.25 or more, it is possible to completely remove the resist pattern without leaving separation residuals. In addition, the resist pattern is formed in the lattice-like shape using the resist having high viscosity of 2 Pa.s or more, which allows the resist to be applied to the substrate in a relatively large thickness up to 100 μm. That is, it is possible to increase the electrode thickness, in other words, it is possible to increase the overall sectional area of the Peltier module in its side view, whereby it is possible to reduce the electric resistance of the electrode.

In accordance with the aspect ratio D/S, when the inter-electrode distance S is reduced relative to the electrode thickness D, it is possible to increase the overall area of the hollows of the resist pattern having the lattice-like shape; hence, it is possible to increase the overall area of the electrodes formed in the hollows. This increases the overall area of the thermoelectric semiconductor elements attached to the electrodes and installed in the Peltier module, whereby it is possible to efficiently transfer heat by use of a relatively large number of electrons and holes.

### BRIEF DESCRIPTION OF THE DRAWINGS

These and other objects, aspects, and embodiments of the present invention will be described in more detail with reference to the following drawings, in which:

FIG. 1A is a plan view showing an upper substrate of a Peltier module viewed from a lower position in accordance with a first embodiment of the invention;

FIG. 1B is a side view partly in cross section showing the structure of the Peltier module including a plurality of thermoelectric semiconductor elements;

FIG. 1C is a plan view showing a lower substrate of the Peltier module viewed from an upper position;

FIG. 2A is a cross sectional view showing that a metal layer is formed on the substrate, which is used for the production of the Peltier module shown in FIGS. 1A to 1C;

FIG. 2B is a cross sectional view showing that a resist is applied to the surface of the metal layer on the substrate;

FIG. 2C is a cross sectional view showing that a resist pattern having hollows is formed by use of a photolithography technique;

FIG. 2D is a cross sectional view showing that copper electrodes are formed in the hollows of the resist pattern;

FIG. 2E is a cross sectional view showing that the resist pattern is dissolved and removed from the substrate by use of organic amine;

FIG. 2F is a cross sectional view showing an assembly in which prescribed portions of the metal layer are removed so that the electrodes are arranged independently of each other;

FIG. 3 diagrammatically shows a layout of essential parts of the Peltier module for the explanation of the operating principle;

FIG. 4 is a longitudinal sectional view of a Peltier module in accordance with a first embodiment of the invention;

FIG. 5 is a cross sectional view of the Peltier module in accordance with the first embodiment of the invention;

FIG. 6 is a graph showing the relationship between an inter-electrode space S and an endothermic value Q with respect to the Peltier module;

FIG. 7 is a graph showing the relationship between the inter-electrode space S and resistance variations before and after an impact test applied to a substrate of the Peltier module;

FIG. 8 is a graph showing the relationship between the inter-electrode space S and resistance variations before and after a vibration test applied to the substrate of the Peltier module;

FIG. 9 is a graph showing the relationship between an aspect ratio D/S and a ratio of a separation residual area with respect to each of resist patterns;

FIG. 10 is a longitudinal sectional view of a Peltier module in accordance with a second embodiment of the invention;

FIG. 11 is a cross sectional view of the Peltier module in accordance with the second embodiment of the invention;

FIG. 12 is a graph showing the relationship between an inter-electrode space S and an endothermic value Q with respect to the Peltier module;

FIG. 13 is a graph showing the relationship between the inter-electrode space S and resistance variations before and after an impact test applied to the substrate of the Peltier module;

FIG. 14 is a graph showing the relationship between the inter-electrode space S and resistance variations before and after a vibration test applied to the substrate of the Peltier module;

FIG. 15 is a graph showing the relationship between an aspect ratio D/S and a ratio of a separation residual area with respect to each of resist patterns;

FIG. 16 is a longitudinal sectional view of a Peltier module in accordance with a third embodiment of the invention;

FIG. 17 is a cross sectional view of the Peltier module in accordance with the third embodiment of the invention;

FIG. 18 is a graph showing the relationship between an inter-electrode space S and an endothermic value Q with respect to the Peltier module;

FIG. 19 is a graph showing the relationship between the inter-electrode space S and resistance variations before and after an impact test applied to the substrate of the Peltier module;

FIG. 20 is a graph showing the relationship between the inter-electrode space S and resistance variations before and after a vibration test applied to the substrate of the Peltier module;

FIG. 21 is a graph showing the relationship between an aspect ratio D/S and a ratio of a separation residual area with respect to each of resist patterns;

FIG. 22A is a plan view showing an upper substrate of a Peltier module viewed from a lower position;

FIG. 22B is a side view partly in cross section showing the structure of the Peltier module including a plurality of thermoelectric semiconductor elements;

FIG. 22C is a plan view showing a lower substrate of the Peltier module viewed from an upper position;

FIG. 23A is a cross sectional view showing that a metal layer is formed on a substrate, which is used for the production of the Peltier module shown in FIGS. 22A to 22C;

FIG. 23B is a cross sectional view showing that a resist is applied to the metal layer on the substrate;

FIG. 23C is a cross sectional view showing that a photolithography technique is applied to cause photochemical reactions on the resist, which is thus transformed into a resist pattern having hollows;

FIG. 23D is a cross sectional view showing that plating is performed to form copper electrodes in the hollows of the resist pattern;

FIG. 23E is a cross sectional view showing that the resist pattern is separated from the substrate;

FIG. 23F is a cross sectional view showing an assembly in which the copper electrodes are arranged with prescribed distances therebetween on the substrate, which is used for the production of the Peltier module; and

FIG. 24 diagrammatically shows a layout of essential parts of the Peltier module for the explanation of the operating principle.

### DESCRIPTION OF THE PREFERRED EMBODIMENTS

This invention will be described in further detail by way of examples with reference to the accompanying drawings.

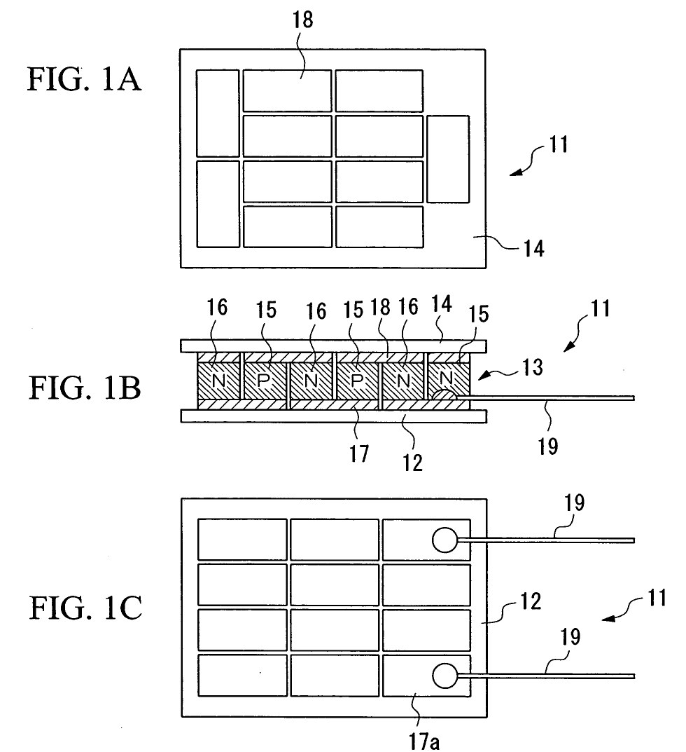

FIGS. 1A to 1C diagrammatically show a Peltier module in accordance with this invention.

Similar to the foregoing Peltier module 1, a Peltier module 11 comprises a ceramic substrate 12, a plurality of thermoelectric semiconductor elements 13, and a ceramic substrate 14. Herein, the thermoelectric semiconductor elements 13 are sandwiched between the substrates 12 and 14, wherein the lower ends thereof are attached to the ‘lower’ substrate 12, and the upper ends thereof are attached to the ‘upper’ substrate 14.

The thermoelectric semiconductor elements 13 comprise a plurality of P-type thermoelectric semiconductor elements 15 and a plurality of N-type thermoelectric semiconductor elements 16, which are alternately arranged and are electrically connected in series, wherein both ends of the thermoelectric semiconductor elements 15 and 16 respectively join a plurality of copper electrodes 17 and 18, which are respectively attached to the substrates 12 and 14. That is, each of the copper electrodes 17 and 18 is connected with a pair of the P-type thermoelectric semiconductor element 15 and the N-type thermoelectric semiconductor element 16. Copper electrodes 17a terminating the copper electrodes 17, which are electrically connected in series, are connected with a power source E (not shown) via leads 19 allowing dc currents to flow therethrough.

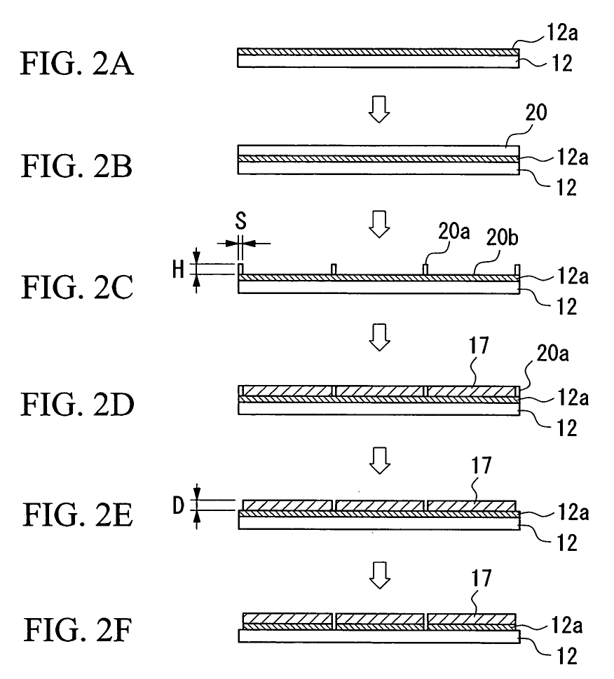

Next, a manufacturing method of the copper electrodes 17 attached to the substrate 12 will be described with reference to FIGS. 2A to 2F, wherein the copper electrodes 18 attached to the substrate 14 can be produced similarly, hence, the description thereof will be omitted.

As shown in FIG. 2A, the surface of the substrate 12 is subjected to cleaning; then, a metal layer 12a serving as a bed for mounting electrodes made of copper and the like is formed on the entire surface of the substrate 12 in a vacuum state by use of a vacuum evaporation device or a sputtering device. As shown in FIG. 2B showing the aforementioned application step, a resist 20 is applied to the entire surface of the metal layer 12a by spin coating and the like.

The resist 20 is an acrylic resist including acrylic polymer, multifunctional acrylate, and photosensitive agent. For example, it is composed of an acrylic resin (whose content ratio ranges from 25% to 35%), a multifunctional acrylate (whose content ratio ranges from 10% to 20%), ester methacrylate (whose content ratio ranges from 0.1% to 10%), benzoin photosensitive agent (whose content ratio ranges from 5% to 15%), and 3-methyl methoxy-propionate (whose content ratio ranges from 30% to 40%).

As shown in FIG. 2C showing the aforementioned hollow formation step, a photolithography technique is used to form a resist pattern 20a having a lattice-like shape, wherein height ‘H’ of the resist pattern 20a is set equal to electrode thickness ‘D’ or more. Herein, the resist pattern 20a is formed in a certain width (i.e., the inter-electrode distance S) such that the aspect ratio D/S is set to 1.25 or more.

The resist 20 is adequately removed so as to retain the resist pattern 20a having hollows 20b as a mask. As shown in FIG. 2D showing the aforementioned electrode formation step, copper plating is performed so as to form copper electrodes 17 in the hollows 20b. In addition, it is possible to perform nickel plating on the metal plating as necessary; and it is possible to perform gold plating on the nickel plating as necessary.

As shown in FIG. 2E showing the aforementioned removal step, the resist pattern 20a is dissolved and removed from the substrate 2 by use of organic amine, e.g., dimethyl sulfoxide. Alternatively, ashing elimination is performed using oxide plasma or ultraviolet ozone, for example. When chemical reactions occurring between the resist pattern 20a and the metal layer 12a produce an affected layer so that the resist pattern 20a cannot be dissolved, the ashing elimination is performed finally in the removal step.

Then, as shown in FIG. 2F, prescribed portions of the metal layer 12a that are exposed on the substrate 12 after the removal of the resist pattern 20a are removed by etching and the like; finally, the copper electrodes 17 are subjected to thermal treatment, thus eliminating stress and distortion thereof.

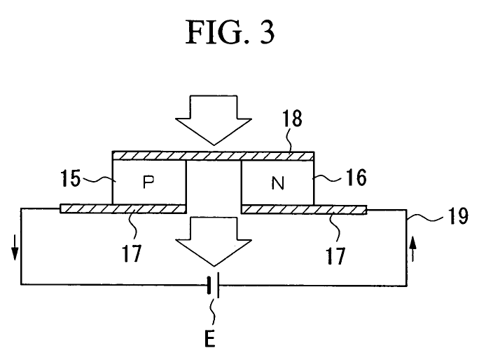

Next, the operating principle of the Peltier module 11 will be described with reference to FIG. 3.

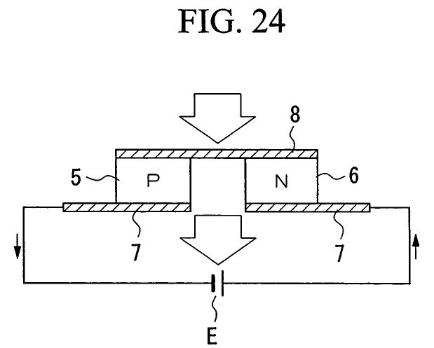

The Peltier module 11 of FIG. 3 operates similarly to the Peltier module 1 shown in FIG. 24. When the power source (or a voltage source) E is activated so that dc currents flow towards the N-type thermoelectric semiconductor element 16, electrons move from the copper electrode 18 to the copper electrode 17 in the N-type thermoelectric semiconductor element 16, while holes move from the copper electrode 18 to the copper electrode 17 in the P-type thermoelectric semiconductor element 15, so that heat is transferred from the copper electrode 18 to the copper electrode 17. At this time, when heat dissipation is sufficiently performed in the side of the copper electrode 17, it is possible to actualize endothermic operation in the side of the copper electrode 18.

In the above, by using the acrylic resist including acrylic polymer, multifunctional acrylate, ester methacrylate, benzoin photosensitive agent, and 3-methyl methoxy-propionate, it is possible to dissolve the resist by use of organic amine when the resist pattern is separated from the substrate after forming electrode layers. Thus, the aspect ratio D/S can be increased to be 1.25 or more without causing separation residuals of the resist. In addition, the resist pattern 20a is formed in the lattice-like shape under the condition where the resist has high viscosity of 2 Pa.s or more; therefore, it is possible to increase the thickness of the resist, which is applied to the substrate, to be 100 μm or so. That is, it is possible to increase the electrode thickness, and it is possible to increase the overall sectional area of the electrodes installed in the Peltier module 11 in its side view. Thus, it is possible to reduce the electric resistance of the electrodes.

As the aspect ratio D/S can be increased in the Peltier module 11, it is possible to reduce the width S of the resist pattern 20a if the electrode thickness D is constant, in other words, it is possible to increase the overall area of the electrodes 17 formed in the hollows 20b of the resist pattern 20a having the lattice-like shape in the upper view of the Peltier module 11. That is, it is possible to increase the total area for installing the thermoelectric semiconductor elements, attached to the electrodes, in the Peltier module. Thus, it is possible to efficiently transfer heat by use of a relatively large number of electrons and holes.

The aforementioned effects demonstrated by the copper electrodes 17 can be similarly applied to the copper electrodes 18. Thus, it is possible to noticeably improve the thermoelectric conversion efficiency of the Peltier module 11.

In the Peltier module 11, the overall area of the electrodes 17 and 18 is increased so that a relatively great amount of heat can be transferred or exchanged due to the movement of electrons and holes in the thermoelectric semiconductor elements 15 and 16. This greatly improves the thermoelectric conversion efficiency of the Peltier module 11, which is thus greatly improved in performance in terms of heat transfer or thermal conduction.

Since the overall area of the copper electrodes 17 and 18 are increased, it is possible to increase the overall contact area between the copper electrodes 17 and the substrate 12 as well as the overall contact area between the copper electrodes 18 and the substrate 14. In addition, it is possible to increase the overall contact area between the copper electrodes 17 and 18 and the thermoelectric semiconductor elements 15 and 16. Thus, it is possible to improve the strength of the Peltier module 11 in terms of the impact resistance and vibration resistance.

Unlike the conventionally used dry film that is subjected to swelling and is separated from the substrate, the resist pattern is removed by dissolution or ashing in the removal step, whereby even when the aspect ratio D/S is increased to 1.25 or more, it is possible to actualize the separation of the resist pattern without causing separation residuals.

The aforementioned Peltier module is produced using the resist having a relatively high viscosity of 2 Pa.s or more; therefore, it is possible to apply the resist onto the substrate in a relatively large thickness of 100 μm or so. This increases the electrode thickness and therefore increases the overall sectional area of the Peltier module in its side view. Thus, it is possible to actualize the “desired” resist pattern on the substrate under the condition of D/S>1.25.

In addition, the overall area of the hollows of the resist pattern having the lattice-like shape is increased; hence, it is possible to increase the overall size of the electrodes, in other words, it is possible to increase the overall area of the electrodes in the Peltier module in its upper view. That is, this invention provides a high-performance Peltier module actualizing transferring of a relatively large amount of heat.

Furthermore, the resist 20 is not necessarily limited to the photosensitive resin compound including acrylic resin, multifunctional acrylate, ester methacrylate, benzoin photosensitive agent, and 3-methyl methoxy-propionate since it is merely required that the resist 20 has high-viscosity characteristics and enables dissolution or ashing elimination under the condition where the aspect ratio of the resist pattern 20a is set to 1.25 or more.

Next, the performance regarding Peltier modules according to first to third embodiments will be described in detail, wherein the same reference numerals are used to designate the corresponding parts among these embodiments.

### 1. First Embodiment

Next, test results regarding the performance of a Peltier module according to a first embodiment of the invention will be described.

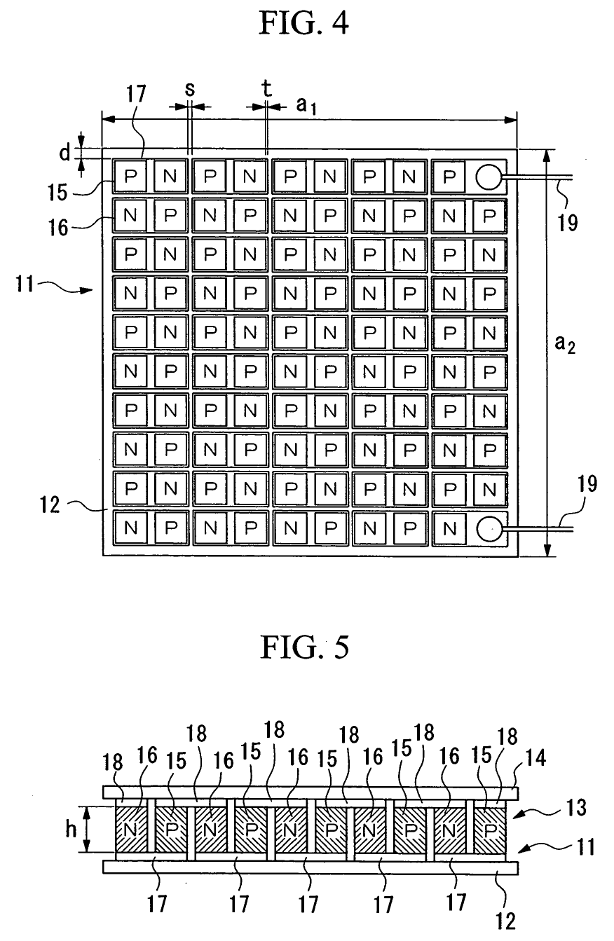

FIGS. 4 and 5 show the Peltier module 11 according to the first embodiment, which is used in testing and whose dimensions and specifications are shown in Table 1. In the Peltier module 11, both of the substrates 12 and 14 have the same rectangular shape having side lengths a₁ and a₂. In addition, an electrode-substrate peripheral margin d defines the distance between the peripheral end of the substrate 12 and the peripheral end of the copper electrode 17 arranged in the outmost position within the substrate 12 as well as the distance between the peripheral ends of the substrate 14 and the peripheral end of the copper electrode 18 arranged in the outmost position within the substrate 14; a chip height h defines the height of the P-type thermoelectric semiconductor element 15 and the height of the N-type thermoelectric semiconductor element 16; and a chip-electrode margin t defines the distance between the peripheral end of the copper electrode 17 and the peripheral end of the P-type thermoelectric semiconductor element 15 or the N-type thermoelectric semiconductor element 16.

TABLE 1

| | |
|---|---|
| Substrate Size a₁ × a₂ | 10 mm × 10 mm |
| Substrate Peripheral Margin d | 100 μm |
| Chip Height h | 1 mm |
| Number of Electrodes on Substrate | 50 |
| (Number of P-type or N-type | (Total 98 elements) |
| thermoelectric semiconductor elements) | |
| Initial Temperature at Substrate 12 | 27° C. |
| Initial Temperature at Substrate 14 | 27° C. |
| Electrode Height D | 100 μm |
| Inter-Electrode Space S | 30 μm, 50 μm, 80 μm, |
| | 100 μm, 150 μm, 200 μm |
| Chip-Electrode Margin t | 50 μm, 100 μm, 150 μm |

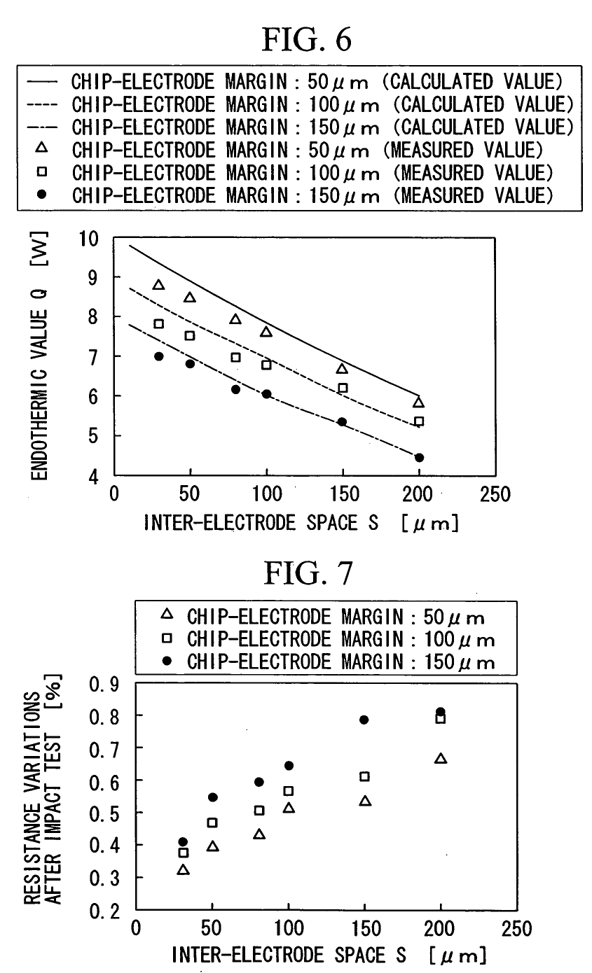

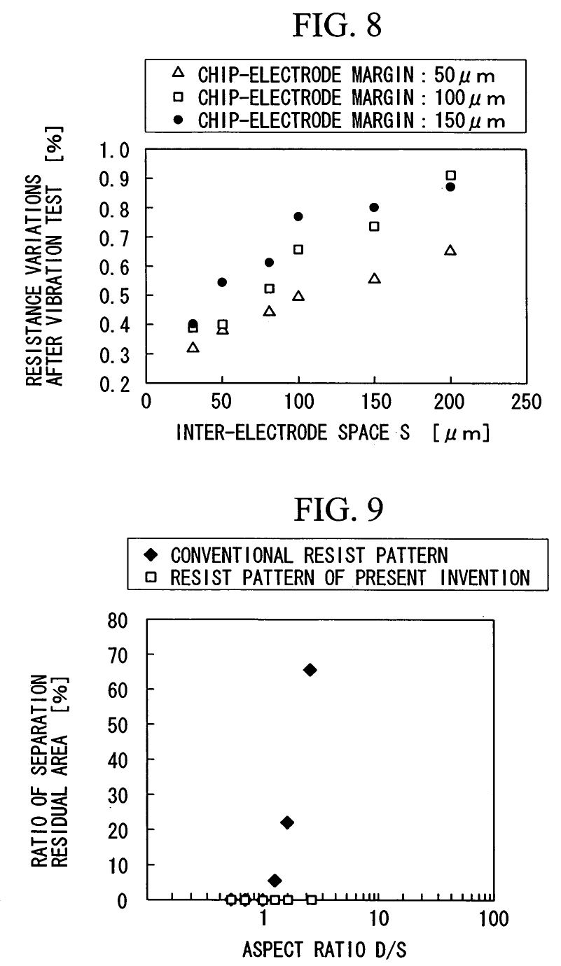

In the above, the inter-electrode space S defines the distance between the adjacent copper electrodes 17 and the distance between the adjacent copper electrodes 18. FIG. 6 is a graph showing the relationship between the inter-electrode space S and the endothermic value Q representing an amount of heat absorbed by the Peltier module 11; FIG. 7 is a graph showing the relationship between the inter-electrode space S and the resistance variations before and after an impact test applied to the substrate 12 or 14; and FIG. 8 is a graph showing the relationship between the inter-electrode space S and the resistance variations before and after a vibration test applied to the substrate 12 or 14.

The impact test is performed based on the MIL standard, namely, STD-883, 2002 Condition B 1500G 0.5 mmSec; and the vibration test is performed based on the MIL standard, namely, STD-883, 2007 Condition A 20G 20-2 kHz.

The aspect ratio D/S is calculated by use of the electrode height D of the copper electrode 17 or 18. FIG. 9 is a graph showing the relationship between the aspect ratio D/S and a ratio of a separation residual area with respect to each of the resist patterns 10a and 20a, which are compared with each other.

FIG. 6 clearly shows that as the inter-electrode space S becomes small, the endothermic value Q becomes large, wherein the endothermic value Q becomes large as the chip-electrode margin t becomes small with respect to the same inter-electrode space S. That is, it is possible to increase the endothermic value Q by decreasing both of the inter-electrode space S and the chip-electrode margin t, thus realizing high performance for the Peltier module 11.

FIG. 7 clearly shows that as the inter-electrode space S becomes large, the ratio of resistance variations before and after the impact test becomes large, wherein the ratio of resistance variations before and after the impact test becomes large as the chip-electrode margin becomes large with respect to the same inter-electrode space S. That is, it is possible to suppress the reduction of the performance of the Peltier module 11 due to impact by decreasing both of the inter-electrode space S and the chip-electrode margin t.

FIG. 8 clearly shows that as the inter-electrode space S becomes large, the ratio of resistance variations before and after the vibration test becomes large, wherein the ratio of resistance variations before and after the vibration test becomes large as the chip-electrode margin t becomes large with respect to the same inter-electrode space S. That is, it is possible to suppress the reduction of the performance of the Peltier module 11 due to vibration by decreasing both of the inter-electrode space S and the chip-electrode margin t.

FIG. 9 clearly shows that as the aspect ratio D/S becomes greater than 1.25, the ratio of the separation residual area of the foregoing resist pattern 10a becomes greater than zero and rapidly increases, whereas the ratio of the separation residual area of the resist pattern 20a according to the present embodiment is substantially maintained at zero. That is, the Peltier module 11 of the present embodiment is advantageous in that the resist pattern 20a can be completely separated from the substrate 12 (or 14) even when the aspect ratio D/S becomes greater than 1.25.

### 2. Second Embodiment

Next, test results regarding the performance of a large-size Peltier module according to a second embodiment of the invention will be described.

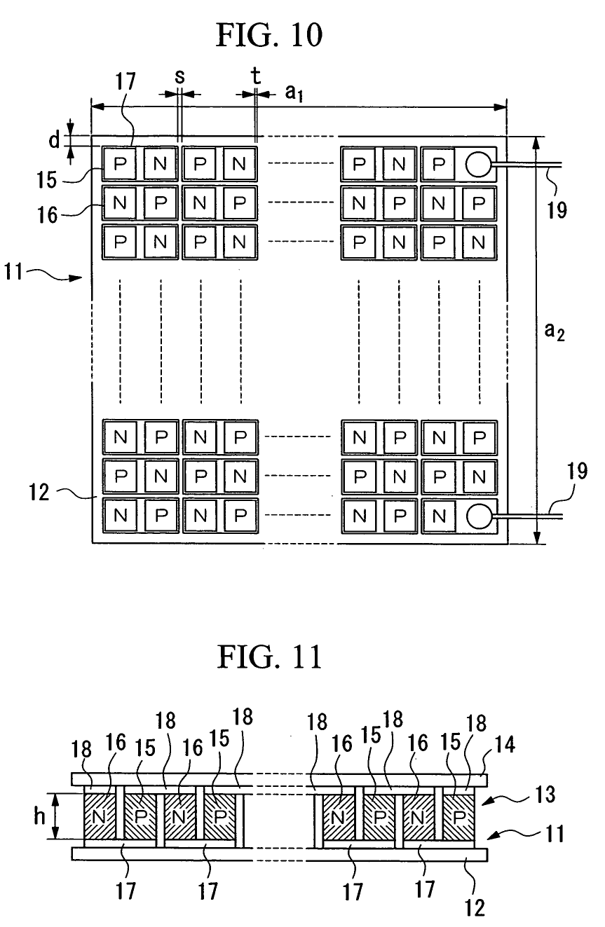

FIGS. 10 and 11 show the Peltier module 11 of the second embodiment which is subjected to testing and whose dimensions and specifications are shown in Table 2, wherein all values regarding the side lengths a₁ and a₂ of the substrate 12 (or 14), electrode-substrate peripheral margin d, chip height h, and chip-electrode margin t are set identical to those of the first embodiment shown in Table 1.

TABLE 2

| | |
|---|---|
| Substrate Size a₁ × a₂ | 40 mm × 40 mm |
| Substrate Peripheral Margin d | 860 μm |
| Chip Height h | 0.81 mm |
| Number of Electrodes on Substrate | 98 |
| (Number of P-type or N-type | (Total 194 elements) |
| thermoelectric semiconductor elements) | |
| Initial Temperature at Substrate 12 | 27° C. |
| Initial Temperature at Substrate 14 | 27° C. |
| Electrode Height D | 160 μm |
| Inter-Electrode Space S | 50 μm, 100 μm, 200 μm, 500 μm |
| Chip-Electrode Margin t | 10 μm, 20 μm, 50 μm |

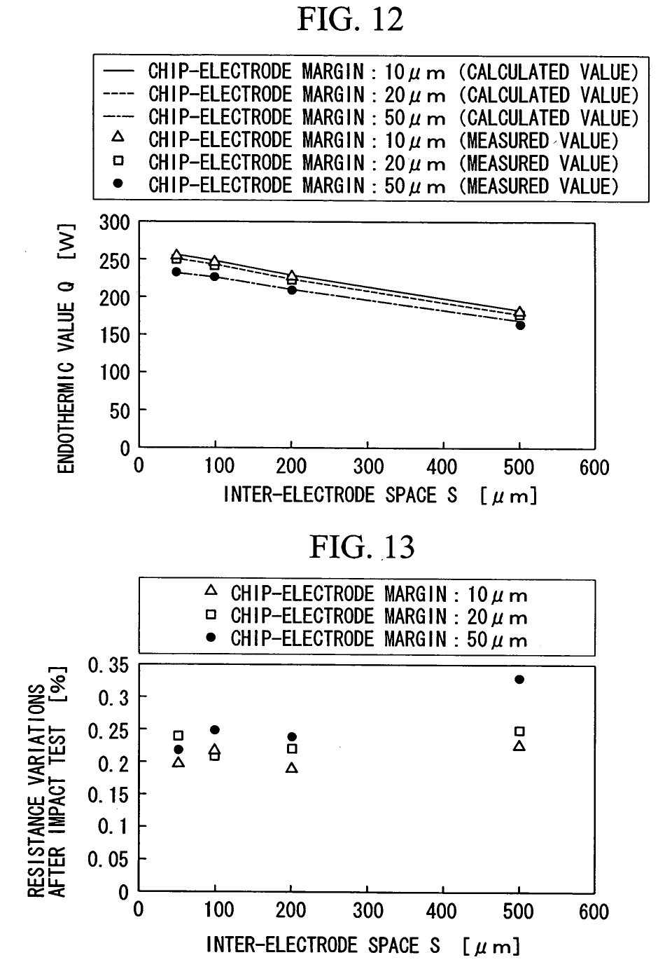

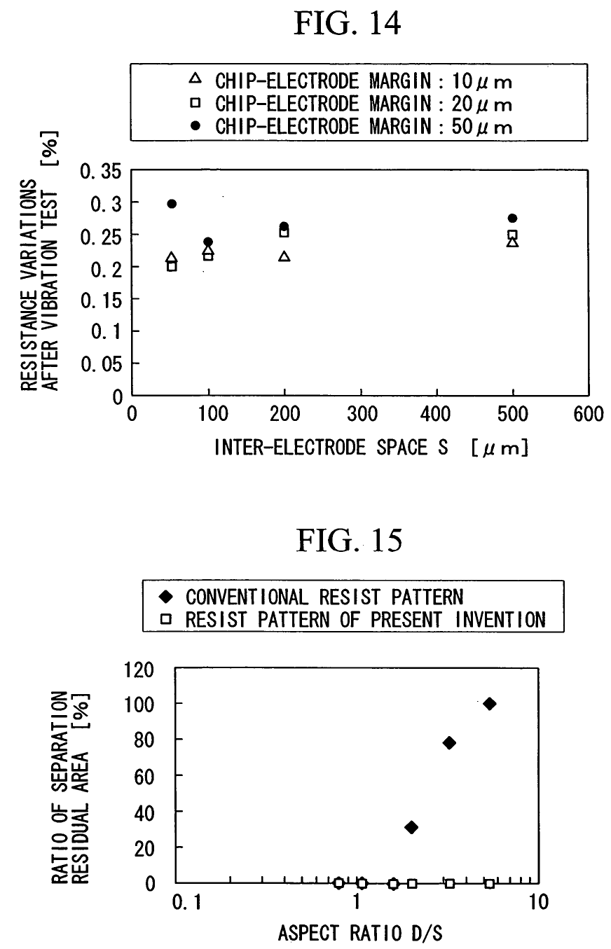

FIG. 12 is a graph showing the relationship between the inter-electrode space S (which is measured between the adjacent copper electrodes 17 or 18) and the endothermic value Q representing an amount of heat absorbed by the Peltier module 11. FIG. 13 is a graph showing the relationship between the inter-electrode space S and the resistance variations before and after an impact test applied to the substrate 12 or 14. FIG. 14 is a graph showing the relationship between the inter-electrode space S and the resistance variations before and after a vibration test applied to the substrate 12 or 14. Incidentally, the impact test and the vibration test are performed in the second embodiment on the basis of the aforementioned standards adapted to the first embodiment.

The aspect ratio D/S is calculated by use of the electrode height D of the copper electrode 17 or 18. FIG. 15 is a graph showing the relationship between the aspect ratio D/S and the ratio of the separation residual area with respect to the resist patterns 10a and 20a, which are compared with each other.

FIG. 12 clearly shows that as the inter-electrode space S becomes small, the endothermic value Q becomes large, wherein the endothermic value Q becomes large as the chip-electrode margin t becomes small with respect to the same inter-electrode space S. That is, it is possible to increase the endothermic value Q by decreasing both of the inter-electrode space S and the chip-electrode margin t, thus realizing high performance for the Peltier module 11.

FIG. 13 clearly shows that as the inter-electrode space S becomes large, the ratio of the resistance variations before and after the impact test becomes large, wherein the ratio of the resistance variations before and after the impact test becomes large as the chip-electrode margin becomes large with respect to the same inter-electrode space S. That is, it is possible to suppress the reduction of the performance of the Peltier module 11 due to impact by decreasing both of the inter-electrode space S and the chip-electrode margin t.

FIG. 14 clearly shows that as the inter-electrode space S becomes large, the ratio of the resistance variations before and after the vibration test becomes large, wherein the ratio of the resistance variations before and after the vibration test becomes large as the chip-electrode margin t becomes large with respect to the same inter-electrode space S. That is, it is possible to suppress the reduction of the performance of the Peltier module 11 due to vibration by decreasing both of the inter-electrode space S and the chip-electrode margin t.

FIG. 15 clearly shows that as the aspect ratio D/S becomes greater than 1.25, the ratio of the separation residual area of the foregoing resist pattern 10a becomes greater than zero and rapidly increases, whereas the ratio of the separation residual area of the resist pattern 20a according to the present embodiment is substantially maintained at zero. That is, the Peltier module 11 of the present embodiment is advantageous in that the resist pattern 20a can be completely separated from the substrate 12 (or 14) even when the aspect ratio D/S becomes greater than 1.25.

### 3. Third Embodiment

Next, test results regarding the performance of a small-size Peltier module according to a third embodiment of the invention will be described.

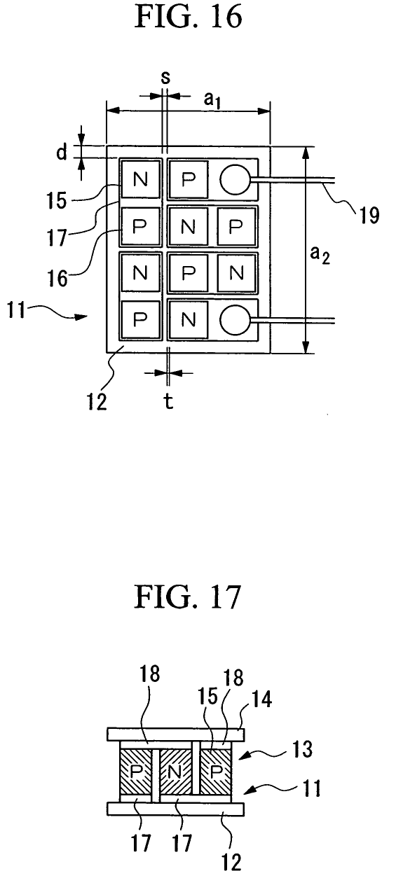

FIGS. 16 and 17 show the Peltier module 11 of the third embodiment which is subjected to testing and whose dimensions and specifications are shown in Table 3, wherein all values regarding the side lengths a₁ and a₂ of the substrate 12 (or 14), electrode-substrate peripheral margin d, chip height h, and chip-electrode margin t are set identical to those of the first and second embodiments.

TABLE 3

| | |
|---|---|
| Substrate Size a₁ × a₂ | 1.2 mm × 1.2 mm |
| Substrate Peripheral Margin d | 50 μm |
| Chip Height h | 0.31 mm |
| Number of Electrodes on Substrate | 6 |
| (Number of P-type or N-type | (Total 10 elements) |
| thermoelectric semiconductor elements) | |
| Initial Temperature at Substrate 12 | 27° C. |
| Initial Temperature at Substrate 14 | 27° C. |
| Electrode Height D | 50 μm |
| Inter-Electrode Space S | 10 μm, 20 μm, 50 μm, 100 μm |
| Chip-Electrode Margin t | 10 μm, 20 μm, 50 μm |

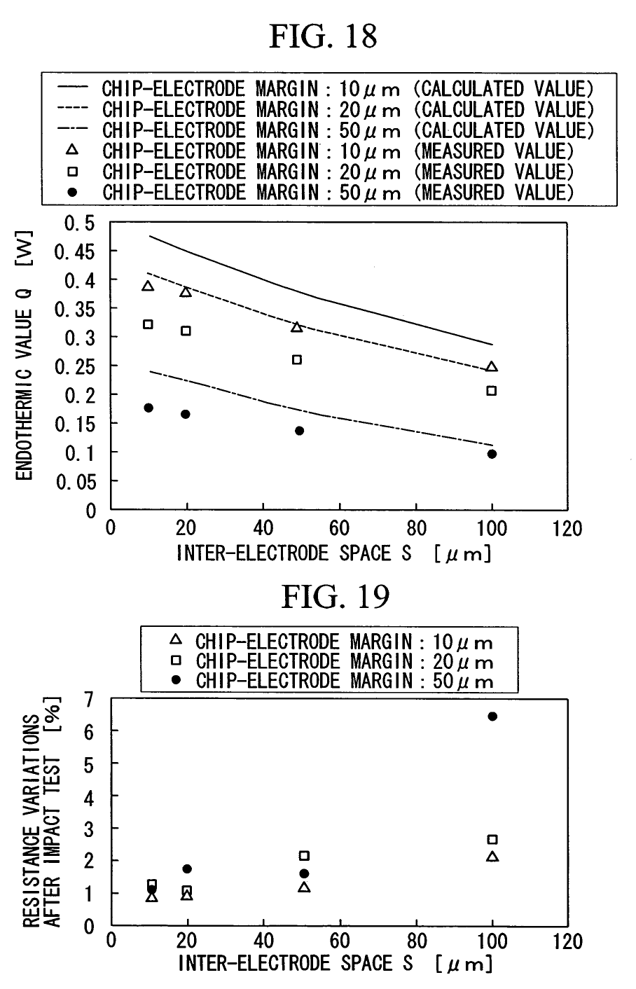

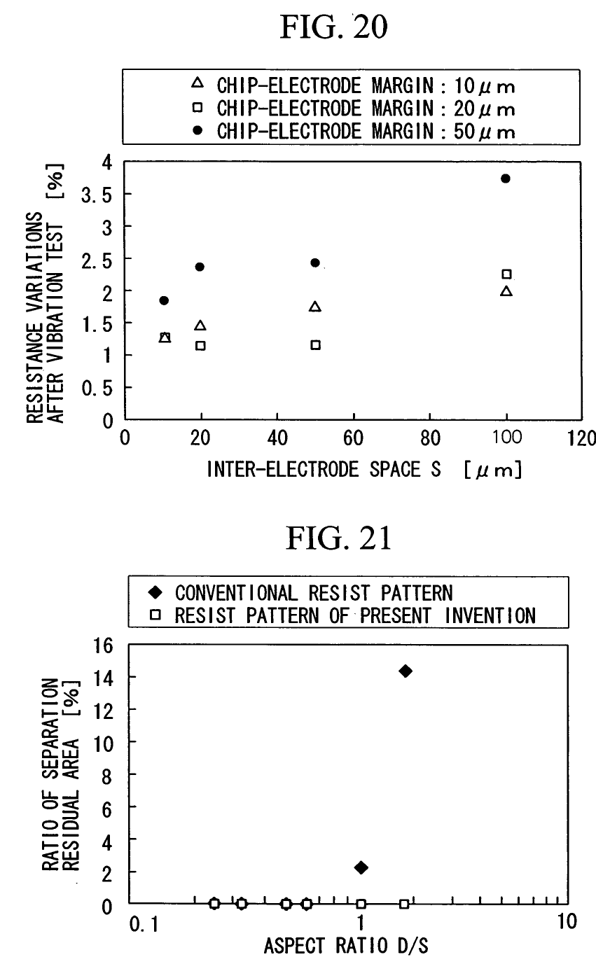

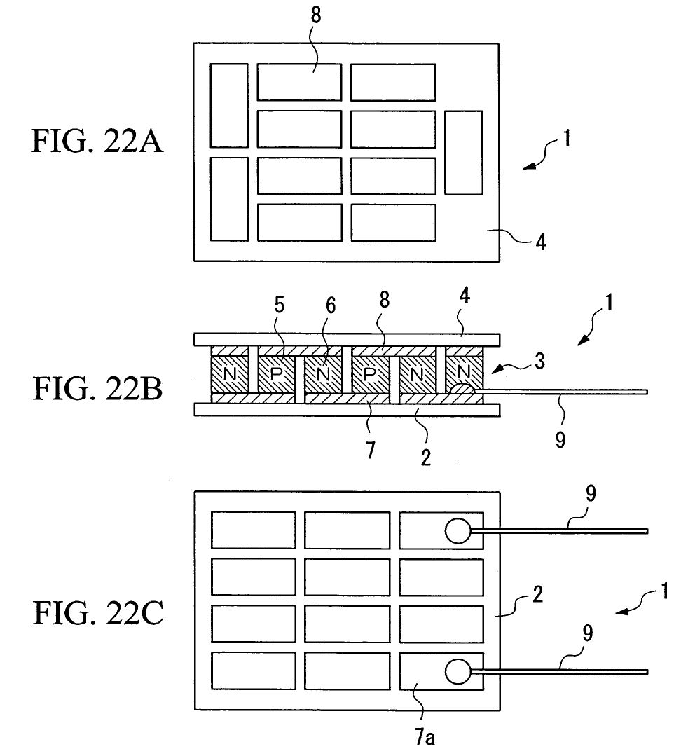

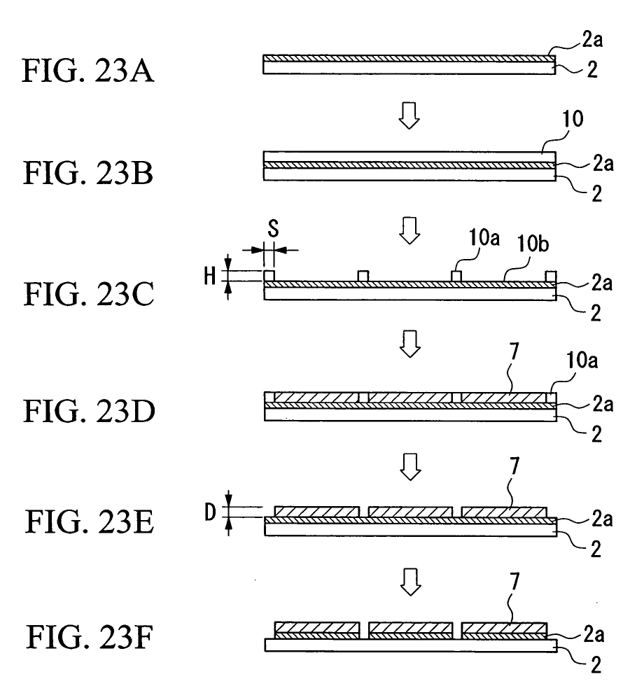

FIG. 18 is a graph showing the relationship between the inter-electrode space S (which is measured between the adjacent copper electrodes 17 or 18) and the endothermic value Q representing an amount of heat absorbed by the Peltier module 11. FIG. 19 is a graph showing the relationship between the inter-electrode space S and the resistance variations before and after an impact test is applied to the substrate 12 or 14. FIG. 20 is a graph showing the relationship between the inter-electrode space S and the resistance variations before and after a vibration test applied to the substrate 12 or 14. Incidentally, the impact test and the vibration test are performed in the third embodiment on the basis of the aforementioned standards adapted to the first and embodiments.

The aspect ratio D/S is calculated by use of the electrode height D of the copper electrode 17 or 18. FIG. 21 is a graph showing the relationship between the aspect ratio D/S and the ratio of the separation residual area with respect to the resist patterns 10a and 20a, which are compared with each other.

FIG. 18 clearly shows that as the inter-electrode space S becomes small, the endothermic value Q becomes large, wherein the endothermic value Q becomes large as the chip-electrode margin t becomes small with respect to the same inter-electrode space S. That is, it is possible to increase the endothermic value Q by decreasing both of the inter-electrode space S and the chip-electrode margin t, thus realizing high performance for the Peltier module 11.

FIG. 19 clearly shows that as the inter-electrode space S becomes large, the ratio of the resistance variations before and after the impact test becomes large, wherein the ratio of the resistance variations before and after the impact test becomes large as the chip-electrode margin becomes large with respect to the same inter-electrode space S. That is, it is possible to suppress the reduction of the performance of the Peltier module 11 due to impact by decreasing both of the inter-electrode space S and the chip-electrode margin t.

FIG. 20 clearly shows that as the inter-electrode space S becomes large, the ratio of the resistance variations before and after the vibration test becomes large, wherein the ratio of the resistance variations before and after the vibration test becomes large as the chip-electrode margin t becomes large with respect to the same inter-electrode space S. That is, it is possible to suppress the reduction of the performance of the Peltier module 11 due to vibration by decreasing both of the inter-electrode space S and the chip-electrode margin t.

FIG. 21 clearly shows that as the aspect ratio D/S becomes greater than 1.25, the ratio of the separation residual area of the foregoing resist pattern 10a becomes greater than zero and rapidly increases, whereas the ratio of the separation residual area of the resist pattern 20a according to the present embodiment is substantially maintained at zero. That is, the Peltier module 11 of the present embodiment is advantageous in that the resist pattern 20a can be completely separated from the substrate 12 (or 14) even when the aspect ratio D/S becomes greater than 1.25.

As this invention may be embodied in several forms without departing from the spirit or essential characteristics thereof, the present embodiments are therefore illustrative and not restrictive, since the scope of the invention is defined by the appended claims rather than by the description preceding them, and all changes that fall within metes and bounds of the claims, or equivalents of such metes and bounds are therefore intended to be embraced by the claims.

1. A manufacturing method for a Peltier module, comprising the steps of:
applying a resist onto a substrate;
deforming the resist into a resist pattern having a lattice-like shape and a plurality of hollows on the substrate;
forming a plurality of electrodes in the plurality of hollows of the resist pattern; and
removing the resist pattern from the substrate,
wherein the resist is made of an acrylic resist including acrylic polymer, multifunctional acrylate, and photosensitive agent.

2. The manufacturing method for a Peltier module according to claim 1, wherein the plurality of electrodes are formed and arranged by use of the resist pattern having the hollows in such a way that an aspect ratio D/S, which is defined using an electrode thickness D and an inter-electrode space S, is set to 1.25 or more.

3. The manufacturing method for a Peltier module according to claim 1, wherein the resist pattern is dissolved and removed from the substrate by use of organic amine.

4. A Peltier module comprising:
a lower substrate;
a plurality of first electrodes attached to the lower substrate;
an upper substrate;
a plurality of second electrodes attached to the upper substrate; and
a plurality of thermoelectric semiconductor elements, which are arranged between the lower substrate and the upper substrate in connection with the first electrodes and the second electrodes respectively,
wherein the first and second electrodes are arranged and formed in such a way that an aspect ratio D/S, which is defined using an electrode thickness D and an inter-electrode space S, is set to 1.25 or more.

5. A Peltier module according to claim 4, wherein both of the lower substrate and the upper substrate are made of ceramics.
